(19) United States
(12) Patent Application Publication
(10) Pub. No.: US 2020/0219423 A1
(43) Pub. Date: Jul. 9, 2020

(54) FLEXIBLE DISPLAY DEVICE AND METHOD OF MANUFACTURING FLEXIBLE DISPLAY DEVICE

(71) Applicant: Sharp Kabushiki Kaisha, Sakai City, Osaka (JP)

(72) Inventors: Tohru OKABE, Sakai City (JP); Shinsuke SAIDA, Sakai City (JP); Hiroki TANIYAMA, Sakai City (JP); Ryosuke GUNJI, Sakai City (JP); Shinji ICHIKAWA, Sakai City (JP); Yoshihiro NAKADA, Sakai City (JP); Hiroharu JINMURA, Sakai City (JP); Akira INOUE, Sakai City (JP)

(21) Appl. No.: 16/471,002

(22) PCT Filed: Sep. 27, 2017
(86) PCT No.: PCT/JP2017/034900

§ 371 Date: Jun. 19, 2019

(51) Int. Cl. G09F 9/30; H01L 27/32; H01L 51/56; H01L 51/52

(52) U.S. Cl. CPC G09F 9/301; H01L 27/3276; H01L 2251/5338; H01L 51/5212; H01L 51/56

(57) ABSTRACT

In a flexible organic EL display device, a first resin layer, which has an opening overlapping with a first conductive member, an opening overlapping with a second conductive member, and an opening and an opening overlapping with a third conductive member, is formed to fill a slit.

### TECHNICAL FIELD

The disclosure relates to a flexible display device and a method of manufacturing a flexible display device.

### BACKGROUND ART

In recent years, a flexible display device including a flexible substrate has been brought to a high degree of attention because the display device can freely be bent.

Further, similarly to other display devices, a frame has strongly been required to be narrower in the field of such flexible display device.

In PTL 1, there is described a flexible display device in which a frame portion including a pad is bent at an angle of 180 degrees and arranged on a back surface of a display surface. With this, the frame portion that is visible from the display surface side is reduced.

### CITATION LIST

### Patent Literature

PTL 1: JP 2014-232300 A (published on Dec. 11, 2014)

### SUMMARY

### Technical Problem

FIG. 8 is a view for illustrating a schematic configuration of a frame portion of a known flexible display device disclosed in PTL 1.

The known flexible display device disclosed in PTL 1 has a configuration in which a frame portion including a pad PD can be bent in a bending region BA at an angle of 180 degrees.

A region including the bending region BA in a flexible substrate 101 includes an etching prevention layer 160. A buffer film 102 being an inorganic film and a gate insulating film 103 being an inorganic film are formed to cover the etching prevention layer 106. Further, on the gate insulating film 103, a gate wiring line GL having a predetermined shape is formed. An interlayer insulating film 104 being an inorganic film is formed to cover the gate wiring line GL.

As illustrated, in the bending region BA on the flexible substrate 101, in order to bend the bending region BA at an angle of 180 degrees, except for the etching prevention layer 106, a bending hole BH passing through the buffer film 102, the gate insulating film 103, and the interlayer insulating film 104 is formed in those three layers, and a link hole LKH is formed in a part of the interlayer insulating film 104, which overlaps with the gate wiring line GL in a plan view.

On the interlayer insulating film 104, a lead wiring line LK, which electrically connects the pad PD and the gate wiring line GL to each other, is formed. In the bending region BA, the lead wiring line LK is formed to be held in contact with tapered parts TP1 and TP2 of the bending hole BH and the etching prevention layer 106.

Further, a protection layer 105 is formed to cover the lead wiring line LK. The lead wiring line LK is electrically connected to the gate wiring line GL through the link hole LKH formed in the interlayer insulating film 104, and is electrically connected to the pad PD through a pad hole PDH formed in the protection layer 105.

However, in the known flexible display device disclosed in PTL 1, the following problems arise due to the configuration of the bending region BA.

As illustrated in FIG. 8, in the bending region BA, the lead wiring line LK is formed to be held in contact with the tapered parts TP1 and TP2 of the bending hole BH and the etching prevention layer 106. In order to form the lead wiring line LK in such a manner without break of the line, the tapered parts TP1 and TP2 of the bending hole BH are required to have a relatively gentle inclination.

Therefore, in order to form the lead wiring line LK without break of the line, there is a problem in that the shape of the bending hole BH formed of the buffer film 102, the gate insulating film 103, and the interlayer insulating film 104 is limited to a shape having side surfaces inclined in a relatively gentle manner.

Thus, in order to solve such problem, it is conceivable to fill the bending hole BH with a flattening resin layer (such as photosensitive polyimide resin) at a height of the interlayer insulating film 104 in the first place and then to form the lead wiring line LK.

In this manner, the bending hole BH formed of the buffer film 102, the gate insulating film 103, and the interlayer insulating film 104 is flattened with the flattening resin layer. Thus, the shape of the bending hole BH is not required to be a specific shape.

However, the flattening resin layer used only for the purpose of filling the bending hole BH is applied to the bending region BA and the interlayer insulating film 104, and then is left only on the bending region BA to flatten the bending hole BH. In this process, a loss of the material for forming the flattening resin layer is large. Thus, there is a problem in that the material for forming the flattening resin layer cannot be used efficiently.

Further, in a case where the flattening resin layer is formed before the lead wiring line LK is formed, the bending hole BH is sealed up with the flattening resin layer, and at the same time, the link hole LKH is also sealed up temporarily. In a case where the link hole LKH has a large depth or the like, in a patterning process, the flattening resin layer formed in the link hole LKH cannot be removed completely. Accordingly, there may be a risk in that connection failure of the lead wiring line LK and the gate wiring line GL is caused due to the flattening resin layer left in the link hole LKH.

The disclosure has been made of the above-mentioned problems, and has an object to provide a flexible display device in which a material for forming a flattening resin layer can be used efficiently and connection failure between wiring lines is suppressed, and to provide a method of manufacturing the flexible display device.

### Solution to Problem

In order to achieve the above-mentioned object, according to one aspect of the disclosure, there is provided a flexible display device including a flexible substrate, and an active element and a display element, which are provided on the flexible substrate. The active element and the display element are provided in a display region. In a periphery of the display region, a frame region is provided, which includes a slit obtained by removing at least part of one or more inorganic films provided on the flexible substrate, and a terminal region including a terminal portion. A first extending wiring line is provided on the display region side on an outer side of the slit, and a second extending wiring line is provided on the terminal region side on an outer side of the slit. In the one or more inorganic films, a first opening is formed to expose the first extending wiring line, and a second opening is formed to expose the second extending wiring line. On the one or more inorganic films, a first conductive member electrically connected to the first extending wiring line through the first opening and a second conductive member electrically connected to the second extending wiring line through the second opening are formed. A third conductive member is formed in the slit. In a plan view, a third opening overlapping with the first conductive member, a fourth opening overlapping with the second conductive member, and a fifth opening and a sixth opening overlapping with the third conductive member are formed in a first resin layer configured to fill the slit and cover the first conductive member, the second conductive member, and the third conductive member. On the first resin layer, a fourth conductive member configured to electrically connect the first conductive member and the third conductive member through the third opening and the fifth opening and a fifth conductive member configured to electrically connect the second conductive member and the third conductive member through the fourth opening and the sixth opening are formed. A bending region overlaps with the slit in a plan view.

With the above-mentioned configuration, the first resin layer is formed to fill the slit and cover the first conductive member and the second conductive member, which are formed on the one or more inorganic films. Thus, a flexible display device, which can suppress loss of a material for forming the first resin layer in the patterning process and enables efficient use of the material for forming the first resin layer, can be achieved.

Further, with the above-mentioned configuration, the first resin layer is formed to cover the first conductive member and the second conductive member, which are formed to fill a first opening and a second opening formed in the one or more inorganic films. Thus, the first resin layer is not formed in the first opening and the second opening. Therefore, connection failure between the wiring lines, which may be caused by the first resin layer, can be suppressed.

In order to achieve the above-mentioned object, according to one aspect of the disclosure, there is provided a method of manufacturing a flexible display device. The flexible display device includes a display region, which includes an active element and a display element, and a frame region, which includes a bending region formed in a periphery of the display region and a terminal region including a terminal portion. The method includes a first step of forming, on a non-flexible substrate, a plurality of inorganic films including a first extending wiring line and a second extending wiring line, which are away from each other, a second step of forming a slit by removing at least part of the plurality of inorganic films in a part of the frame region, and forming, in the plurality of inorganic films, a first opening to expose the first extending wiring line and a second opening to expose the second extending wiring line, a third step of forming a first conductive member electrically connected to the first extending wiring line through the first opening and a second conductive member electrically connected to the second extending wiring line through the second opening on the plurality of inorganic films, and forming a third conductive member in the slit, a fourth step of forming a first resin layer configured to fill the slit and cover the first conductive member, the second conductive member, and the third conductive member, and forming, in the first resin layer, a third opening overlapping with the first conductive member, a fourth opening overlapping with the second conductive member, and a fifth opening and a sixth opening overlapping with the third conductive member in a plan view, a fifth step of forming, on the first resin layer, a fourth conductive member electrically connecting the first conductive member and the third conductive member through the third opening and the fifth opening and a fifth conductive member electrically connecting the second conductive member and the third conductive member through the fourth opening and the sixth opening so that a region between the fourth conductive member and the fifth conductive member is prevented from overlapping with the slit in a plan view, a sixth step of forming a second resin layer to cover the fourth conductive member, the fifth conductive member, and the first resin layer, a seventh step of peeling off the non-flexible substrate, and an eighth step of attaching a flexible substrate to a surface from which the non-flexible substrate is peeled off.

With the above-mentioned method, the first resin layer formed in the fourth step is formed to fill the slit and cover the first conductive member and the second conductive member, which are formed on the plurality of inorganic films. Thus, in the patterning process for forming the third opening, the fourth opening, the fifth opening, and the sixth opening, a method of manufacturing a flexible display device, which can suppress the loss of the material for forming the first resin layer and enables efficient use of the material for forming the first resin layer, can be achieved.

Further, with the above-mentioned method, in the second step, on the plurality of inorganic films, the first opening is formed to expose the first extending wiring line, and the second opening is formed to expose the second extending wiring line. After that, in the third step, on the plurality of inorganic films, the first conductive member electrically connected to the first extending wiring line through the first opening and the second conductive member electrically connected to the second extending wiring line through the second opening are formed. Subsequently, in the fourth step, the first resin layer is formed to cover the first conductive member and the second conductive member, which are formed on the plurality of inorganic films. Thus, the first resin layer is not formed in the first opening and the second opening. Therefore, connection failure between the wiring lines, which may be caused by the first resin layer, can be suppressed.

### Advantageous Effects of Disclosure

According to an aspect of the disclosure, the flexible display device in which the material for forming the flattening resin layer can be used efficiently and connection failure between the wiring lines is suppressed, and the method of manufacturing the flexible display device can be provided.

### BRIEF DESCRIPTION OF DRAWINGS

FIG. 1A to FIG. 1G are views for illustrating manufacturing processes of a display region of a flexible organic EL display device according to a first embodiment of the disclosure, a slit including a bending region, and a terminal region.

FIG. 2A is a view for illustrating a schematic configuration of the vicinity of the slit including the bending region of the flexible organic EL display device according to the first embodiment. FIG. 2B is a view for illustrating a schematic configuration of a display region of the flexible organic EL display device according to the first embodiment.

FIG. 3 is a plan view of the vicinity of the slit including the bending region of the flexible organic EL display device according to the first embodiment, which is illustrated in FIG. 2A.

FIG. 4 is a view for illustrating a schematic configuration of a vicinity of a slit including a bending region of a flexible organic EL display device according to a second embodiment of the disclosure.

FIG. 5A to FIG. 5H are views for illustrating manufacturing processes of a display region of a flexible organic EL display device being a comparative example, a slit including a bending region, and a terminal region.

FIG. 6A is a view for illustrating a schematic configuration of the vicinity of the slit including the bending region of the flexible organic EL display device being the comparative example. FIG. 6B is a view for illustrating a schematic configuration of a display region of the flexible organic EL display device in the comparative example.

FIG. 7A is a plan view of the flexible organic EL display device being the comparative example, which is illustrated in FIG. 6A and FIG. 6B. FIG. 7B is an end face view of the line A-B illustrated in FIG. 7A for illustrating a state before the flexible organic EL display device being the comparative example is bent. FIG. 7C is an end face view of the line A-B illustrated in FIG. 7A for illustrating a state in which the flexible organic EL display device being the comparative example is bent in the bending region.

FIG. 8 is a view for illustrating a schematic configuration of a frame portion of a known flexible display device disclosed in PTL 1.

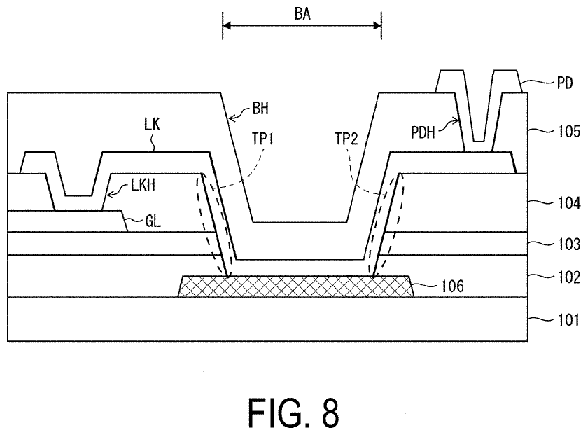

### DESCRIPTION OF EMBODIMENTS

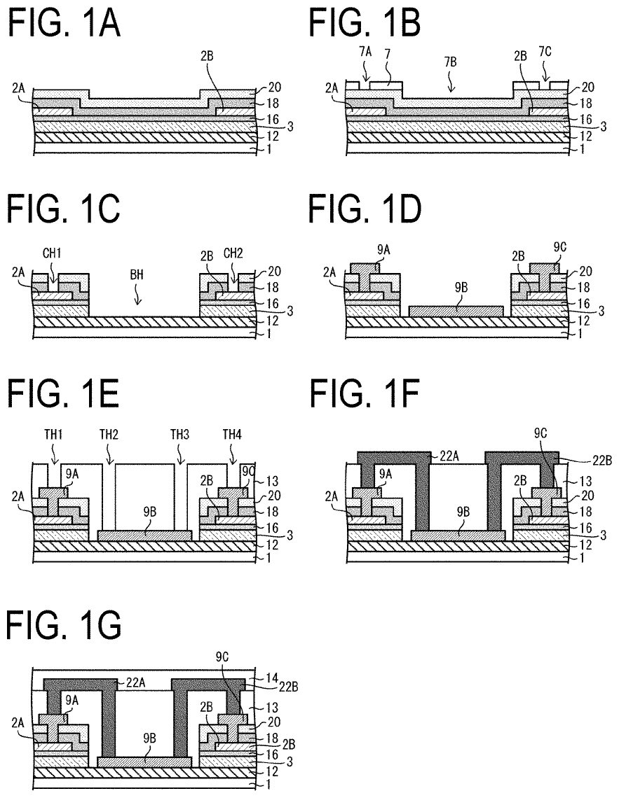

A description follows regarding embodiments of the disclosure, with reference to FIG. 1A to FIG. 7C. Hereinafter, for convenience of descriptions, a configuration having the same functions as those of a configuration described in a specific embodiment are denoted by the same reference numerals, and its descriptions may be omitted.

Note that, in the following embodiments, description is made of an organic electro luminescence (EL) element as an example of a display element (optical element). However, the disclosure is not limited thereto, and may be, for example, a reflective-type liquid crystal display element, in which luminance and transmittance are controlled by a voltage and background light is not required.

The display element (optical element) is an optical element whose luminance and transmittance are controlled by an electric current, and examples of the electric current-controlled optical element include an organic electro luminescence (EL) display provided with an organic light emitting diode (OLED), an EL display such as an inorganic EL display provided with an inorganic light emitting diode, or a quantum dot light emitting diode (QLED) display provided with a QLED.

### First Embodiment

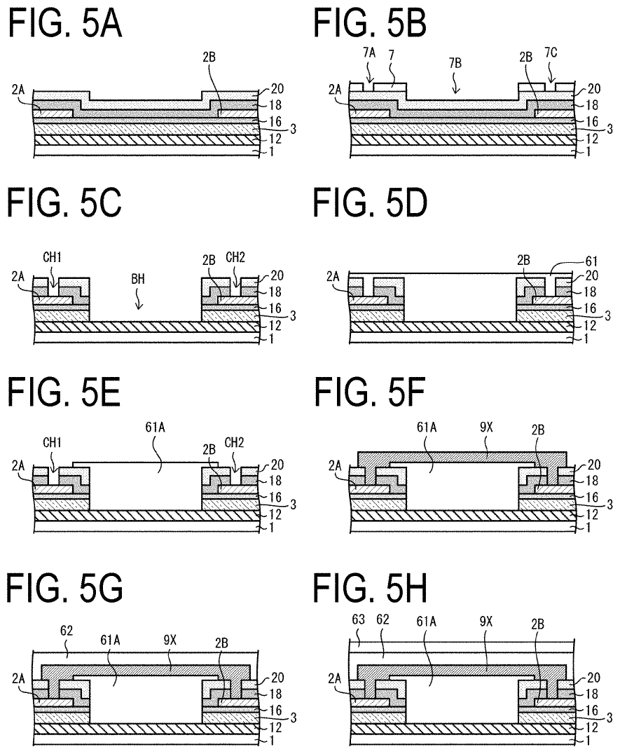

In the following, with reference to FIG. 5A to FIG. 7C, problems of a flexible organic EL display device 70 being a comparative example are described. With reference to FIG. 1A to FIG. 3, a flexible organic EL display device 50 according to the first embodiment of the disclosure is described.

FIG. 5A to FIG. 5H are views for illustrating manufacturing processes of a non-display region including a bending region of a flexible organic EL display device 70 being the comparative example.

As illustrated in FIG. 5A, first, a polyimide resin layer (PI layer) 12 is applied on a glass substrate 1 being a non-flexible substrate.

In this comparative example, in consideration of a high-temperature process in the post-processes and laser light passing through the glass substrate in the following process, description is made of a case where the glass substrate 1 having high heat resistance is used. However, the disclosure is not limited to a glass substrate as long as the substrate is resistible in the high-temperature process included in the post-processes and laser light can pass through the substrate in the post-process.

Note that, in this comparative example, the polyimide resin layer 12 is used so that laser light is emitted from the glass substrate 1 side in the post-process to perform ablation at a boundary surface between the polyimide resin layer 12 and the glass substrate 1 and the glass substrate 1 is peeled off from the polyimide resin layer 12. However, the disclosure is not limited thereto. A resin layer other than a polyimide resin layer (for example, an epoxy resin layer and a polyamide resin layer) may be used as long as the glass substrate 1 can be peeled off in the post-process.

Next, a moisture-proof layer 3 (also referred to as a barrier layer) is formed on the polyimide resin layer 12.

The moisture-proof layer 3 is a layer for preventing moisture or impurities from reaching an active element or a display element when the flexible organic EL display device 70 is used. The moisture-proof layer 3 may be formed of a silicon oxide film, a silicon nitride film, a silicon oxynitride film, or a layered film of those films by, for example, CVD.

Further, a gate insulating layer 16 is formed on the moisture-proof layer 3.

The gate insulating film 16 may be formed of a silicon oxide (SiOx) film, a silicon nitride (SiNx) film, or a layered film of those films by, for example, the CVD method.

Further, a first extending wiring line 2A and a second extending wiring line 2B are formed away from each other on the gate insulating layer 16.

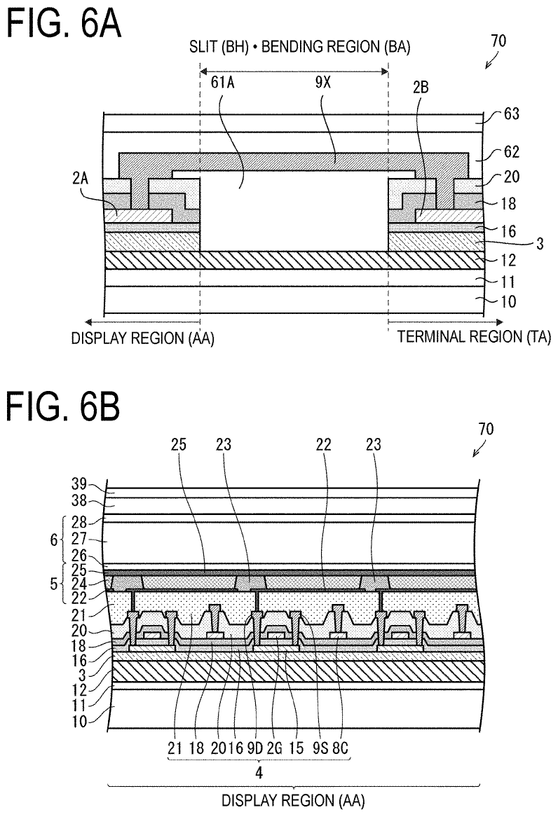

Note that, the first extending wiring line 2A in a display region AA (see FIG. 6A and FIG. 6B) extends to the display region side (not illustrated), and the second extending wiring line 2B in a terminal region TA (see FIG. 6A and FIG. 6B) including a terminal portion (not illustrated) extends to the terminal region side (not illustrated).

In this comparative example, description is made of a case where the first extending wiring line 2A and the second extending wiring line 2B are extending wiring lines of gate electrodes. However, the disclosure is not limited thereto. A type of the extending wiring lines 2A and 2B is not particularly limited as long as the wiring lines are dedicated for signals supplied from the terminal portion (not illustrated) included in the terminal region TA (see FIG. 6A and FIG. 6B).

Further, a first insulating layer 18 is formed to cover the first extending wiring line 2A, the second extending wiring line 2B, and the gate insulating layer 16.

The first insulating layer 18 is an insulating film layer for forming a capacitor (capacitance element) included in the display region AA (not illustrated), and may be a silicon nitride (SiNx) film formed by, for example, the CVD method.

Further, a second insulating layer 20 is formed to cover the first insulating layer 18.

The second insulating layer 20 may be formed of a silicon oxide (SiOx) film, a silicon nitride (SiNx) film, or a layered film of those films by, for example, the CVD method.

After that, as illustrated in FIG. 5B, a resist film 7 having an opening 7A, an opening 7B, and an opening 7C is formed on the second insulating layer 20.

The opening 7A and the opening 7C are openings for forming a contact hole CH1 and a contact hole CH2 in the first insulating layer 18 and the second insulating layer 20, and the opening 7B is an opening for forming a slit (also referred to as a bending hole) (BH) in the moisture-proof layer 3, the gate insulating layer 16, the first insulating layer 18, and the second insulating layer 20.

In this comparative example, dry etching is performed with the resist film 7 illustrated in FIG. 5B as a mask. Accordingly, as illustrated in FIG. 5C, the first insulating layer 18 and the second insulating layer 20 are removed, and the contact hole CH1 are the contact hole CH2 are formed in the first insulating layer 18 and the second insulating layer 20. At the same time, the moisture-proof layer 3, the gate insulating layer 16, the first insulating layer 18, and the second insulating layer 20 are removed, and the slit (BH) is formed.

Note that, at the time of the dry etching, the first extending wiring line 2A and the second extending wiring line 2B function as etching prevention layers for the moisture-proof layer 3 and the gate insulating layer 16 being lower layers. Thus, the contact hole CH1, the contact hole CH2, and the slit (BH) can be formed in the same dry etching process.

Note that, in this comparative example, description is made of a case where the contact hole CH1, the contact hole CH2, and the slit (BH) are formed by dry etching. However, the disclosure is not limited thereto, and wet etching may be used.

Note that, in consideration of a 180-degree bend, bending easiness, and the like in the bending region (BA) of the flexible organic EL display device, it is preferred that the slit (BH) be formed by removing the entire layered films formed of inorganic films. However, in the layered films formed of the inorganic films, only one or more upper films may be removed to form the slit (BH).

Next, as illustrated in FIG. 5D, a first photosensitive PI layer 61 is applied on the entire terminal region TA (see FIG. 6A and FIG. 6B) including the display region AA (see FIG. 6A and FIG. 6B) and the terminal portion (not illustrated) on the glass substrate 1 to fill the contact hole CH1, the contact hole CH2, and the slit (BH).

The process of applying the first photosensitive PI layer 61 is performed by using, for example, a slit coater and a spin coater. However, the disclosure is not limited thereto.

The first photosensitive PI layer 61 is a polyimide resin containing a photosensitive material, and a flattening film for leveling a lower layer.

Note that, the first photosensitive PI layer 61 may be a positive-working type or a negative-working type. In this comparative example, a positive-working type in which an exposed part is removed is used.

Further, as illustrated in FIG. 5E, the first photosensitive PI layer 61 formed on the entire glass substrate 1 is subjected to exposure and development, and a first photosensitive PI layer 61A having a predetermined shape slightly larger than a portion for filling the slit (BH).

As described above, in the process for patterning the first photosensitive PI layer 61, the first photosensitive PI layer 61A having the predetermined shape is left, and all the other portions of the first photosensitive PI layer 61 formed on the entire glass substrate 1 are removed. Accordingly, a loss of the material of the first photosensitive PI layer 61, which is relatively expensive, is large, and this is one of the causes of increasing manufacturing cost of the flexible organic EL display device.

Further, in the process of patterning the first photosensitive PI layer 61, there may be a possibility that the first photosensitive PI layer 61 formed in the contact hole CH1 and the contact hole CH2 cannot be removed completely depending on a shape and a depth of the contact hole CH1 and the contact hole CH2.

When a residue is generated in the contact hole CH1 and the contact hole CH2, there is a problem in that the connection failure between the wiring lines is caused.

After that, as illustrated in FIG. 5F, a conductive member 9X is formed on the second insulating layer 20 and the first photosensitive PI layer 61A having the predetermined shape. The conductive member 9X is electrically connected to the first extending wiring line 2A through the contact hole CH1, and is electrically connected to the second extending wiring line 2B through the contact hole CH2.

Then, after a second photosensitive PI layer 62 is formed on the entire glass substrate 1, exposure and development are performed. As illustrated in FIG. 5G, the second photosensitive PI layer 62 remains to cover the conductive member 9X, the second insulating layer 20, and the first photosensitive PI layer 61A having the predetermined shape.

Further, after a third photosensitive PI layer 63 is formed on the entire glass substrate 1, exposure and development are performed. As illustrated in FIG. 5H, the third photosensitive PI layer 63 remains to cover the second photosensitive PI layer 62 and a further conductive member layer (not illustrated).

FIG. 6A is a view for illustrating a schematic configuration of the vicinity of the slit (BH) including the bending region (BA) of the flexible organic EL display device 70. FIG. 6B is a view for illustrating a schematic configuration of the display region (AA) of the flexible organic EL display device 70.

Note that, description is made of a case where the flexible organic EL display device 70 illustrated in FIG. 6A and FIG. 6B is manufactured by a laser lift off process (LLO process) as below. However, the disclosure is not limited thereto.

The laser light is emitted from a side of the glass substrate 1 being a non-flexible substrate illustrated in FIG. 5H, and ablation is caused at a boundary surface between the polyimide resin layer 12 and the glass substrate 1.

Then, the glass substrate 1 is peeled off from the polyimide resin layer 12, and a film substrate 10 being a flexible substrate is attached to the polyimide resin layer 12 through intermediation of an adhesive layer 11 provided on one surface of the film substrate 10. In this manner, the flexible organic EL display device 70 illustrated in FIG. 6A and FIG. 6B is completed.

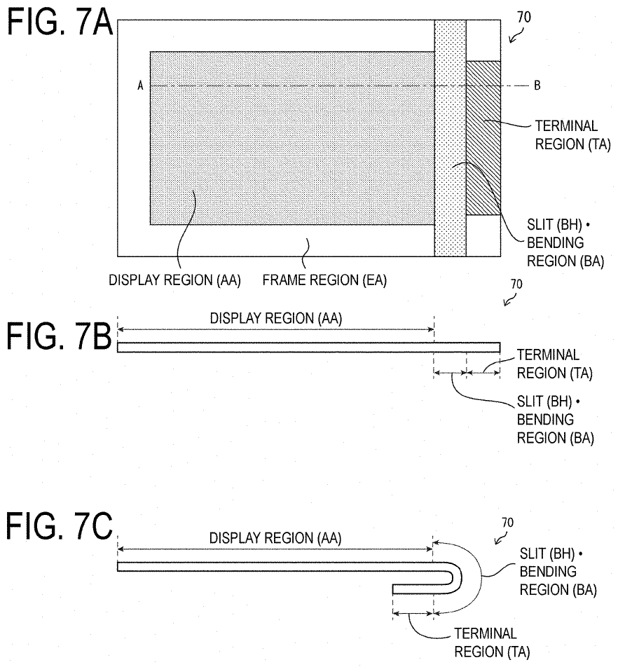

In a frame region (EA) (see FIG. 7A to FIG. 7C) of the flexible organic EL display device 70 illustrated in FIG. 6A, the slit (BH) formed by removing the moisture-proof layer 3, the gate insulating layer 16, the first insulating layer 18, and the second insulating layer 20 is the bending region (BA).

The display region (AA) of the flexible organic EL display device 70 illustrated in FIG. 6B includes a TFT layer 4 including a thin film transistor element (TFT) element being an active element and an organic EL display element 5 being a display element on the TFT layer 4.

Note that, the active element used for a circuit other than a pixel circuit may be provided in the frame region (EA) other than the display region (AA).

As illustrated, the polyimide resin layer 12 is formed on the film substrate 10 through intermediation of the adhesive layer 11, and the moisture-proof layer 3 is formed on the polyimide resin layer 12. Further, the TFT layer 4 including the gate insulating layer 16, the first insulating layer 18, the second insulating layer 20, and an organic interlayer layer 21 is formed on the moisture-proof layer 3. Then, on the TFT layer 4, the organic EL display element 5 being an electro-optic element is formed. Further, a sealing layer 6 including an inorganic sealing films 26 and 28 and an organic sealing film 27 is formed to cover the organic EL display element 5. A touch panel 39 including a protection layer is attached to the inorganic sealing film 28 through intermediation of an adhesive layer 38 formed of an optical clear adhesive (OCA) or an optical clear resin (OCR).

Note that, as the material of the film substrate 10, a film formed of, for example, a polyethylene terephthalate (PET) can be exemplified.

The TFT layer 4 includes a semiconductor film 15, the gate insulating film 16 that is formed above the semiconductor film 15, a gate electrode 2G that is formed above the gate insulating film 16, the first insulating layer 18 and the second insulating layer 20 that are formed above the gate electrode 2G, a capacity electrode C that is formed above the first inorganic insulating layer 18 and a terminal of the capacity electrode C, a source wiring line 9S and a drain wiring line 9D that are formed above the second insulating layer 20, and an organic interlayer film (flattening film) 21 that is formed above the source wiring line 9S and the drain wiring line 9D.

Note that, a thin film transistor (TFT) is formed to include the semiconductor film 15, the gate insulating layer 16, and the gate electrode 2G, and a capacity element is formed to include a capacity counter electrode (not shown) in which the capacity electrode C, the first insulating layer 18, and the gate electrode 2G are formed in the same layer.

The semiconductor film 15 is formed of, for example, low temperature polysilicon (LTPS) or an oxide semiconductor. The gate electrode 2G, the source electrode 9S, the drain electrode 9D, and the terminal are formed of a metal single layer film or a layered film containing, for example, at least one of aluminum (Al), tungsten (W), molybdenum (Mo), tantalum (Ta), chromium (Cr), titanium (Ti), or copper (Cu). Note that, in FIG. 6B, the TFT is illustrated to have a top gate structure in which the semiconductor film 15 is the channel, but the TFT may have a bottom gate structure (when the TFT channel is the oxide semiconductor, for example).

Note that, in a case where the semiconductor film 15 is, for example, an oxide semiconductor film containing indium (In), gallium (Ga), and zinc (Zn) or an oxide semiconductor film containing indium (In), gallium (Ga), and zinc (Zn), which is manufactured in a manufacturing process of low-temperature poly-silicon (LTPS), a layered film containing copper (Cu) and titanium (Ti) may be used for the material for forming the source electrode 9S and the drain electrode 9D.

The organic interlayer film 21 may be formed of a coatable photosensitive organic material, such as polyimide and acrylic.

Above the organic interlayer layer 21, there are formed a first electrode 22 (for example, an anode), an organic insulating film (also referred to as an edge cover layer) 23 covering an edge of the first electrode 22, an EL layer 24 including a light-emitting layer, which is formed above the first electrode 22, and a second electrode 25 formed above the EL layer 24. The organic EL display element 5 is formed of the first electrode 22, the EL layer 24, and the second electrode 25. The organic insulating film 23 in the display region AA functions as a bank (pixel partition) that defines subpixels.

Note that, the organic insulating film 23 may be formed of a coatable photosensitive organic material such as polyimide resin, acrylic resin, epoxy resin, and polyamide resin.

The EL layer 24 is formed in a region (subpixel region) surrounded by the organic insulating film 23 by a vapor deposition method or an ink-jet method. For example, the EL layer 24 including a light-emitting layer, which is provided with the organic EL display element 5, is formed by layering a hole injecting layer, a hole transport layer, a light emitting layer, an electron transport layer, and an electron injecting layer in the stated order, with the hole injecting layer being the bottom layer. Note that one or more layers of the EL layer 24 may be a shared layer (shared by a plurality of pixels).

The first electrode (anode) 22 is formed by layering, for example, indium tin oxide (ITO) and an alloy containing silver (Ag), and has light reflectivity. The second electrode (for example, a cathode) 25 is a common electrode, and may be formed of a transparent metal such as indium tin oxide (ITO) or indium zinc oxide (IZO).

In the organic EL display element 5, when a drive current flows between the first electrode 22 and the second electrode 25, holes and electrons recombine in the EL layer 24 to form excitons, and when the excitons fall to their ground state, light is emitted.

The sealing layer 6 covers the organic EL display element 5, and prevents penetration of foreign matters, such as water and oxygen, into the organic EL display element 5. The sealing layer 6 includes a first inorganic sealing film 26 covering the organic insulating film 23 and the second electrode 25, an organic sealing film 27 that functions as a buffer film formed above the first inorganic sealing film 26, and a second inorganic sealing film 28 covering the first inorganic sealing film 26 and the organic sealing film 27.

Each of the first inorganic sealing film 26 and the second inorganic sealing film 28 may be a silicon oxide film, a silicon nitride film, a silicon oxynitride film, or a layered film thereof formed by a CVD method using a mask. The organic sealing film 27 is a transparent organic insulating film that is thicker than the first inorganic sealing film 26 and the second inorganic sealing film 28, and may be formed of a coatable photosensitive organic material such as polyimide and acrylic. For example, after coating the first inorganic sealing film 26 with an ink containing such an organic material using the ink-jet method, the ink is hardened by UV irradiation.

FIG. 7A is a plan view of the flexible organic EL display device 70 being the comparative example, which is illustrated in FIG. 6A and FIG. 6B. FIG. 7B is an end face view of the line A-B illustrated in FIG. 7A for illustrating a state before the flexible organic EL display device 70 being the comparative example is bent. FIG. 7C is an end face view of the line A-B illustrated in FIG. 7A for illustrating a state in which the flexible organic EL display device 70 being the comparative example is bent in the bending region (BA).

As illustrated in FIG. 7A, in the flexible organic EL display device 70, the frame region (EA) is in the periphery of the display region (AA), and the terminal region (TA) including the terminal portion (not shown) and the slit (BH) including the bending region (BA) are included in the frame region (EA).

Note that, in the flexible organic EL display device 70, the slit (BH) is, for example, an opening formed from one end to the other end.

As described above, in the case of the flexible organic EL display device 70 being the comparative example, there are the problems in that the loss of the material for the first photosensitive PI layer 61, which is relatively expensive, is large and that the manufacturing cost of the flexible organic EL display device 70 cannot be suppressed. At the same time, a residue of the first photosensitive PI layer 61 is liable to remain in the contact hole CH1 and the contact hole CH2, which is liable to cause a structural problem of connection failure between the wiring lines.

In view of the above, the inventors of the disclosure propose a flexible display device (the flexible organic EL display device 50), which can suppress increase of the manufacturing cost and suppress connection failure between the wiring lines, and a method of manufacturing the flexible display device as described below.

Now, with reference to FIG. 1A to FIG. 3, description is made of a method of manufacturing the flexible organic EL display device 50 according to the first embodiment of the disclosure and a configuration of the flexible organic EL display device 50.

Note that, for convenience of description, members having the same functions as those of the members illustrated in the diagrams of the flexible organic EL display device 70 being the comparative example described above are denoted by the same reference numerals, and description thereof is omitted.

FIG. 1A to FIG. 1G are views for illustrating manufacturing processes of a non-display region including a bending region of the flexible organic EL display device 50.

The processes illustrated in FIG. 1A, FIG. 1B, and FIG. 1C are the same as those illustrated in FIG. 5A, FIG. 5B, and FIG. 5C described above, and description thereof is omitted.

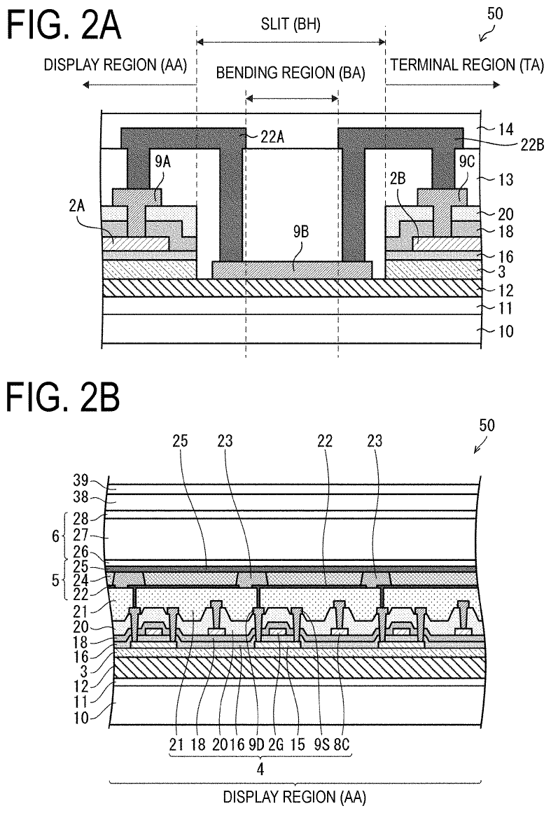

As illustrated in FIG. 1D, the first extending wiring line 2A in the display region AA (see FIG. 2A and FIG. 2B) extends to the display region side (not illustrated), and the second extending wiring line 2B in the terminal region TA (see FIG. 2A and FIG. 2B) including the terminal portion (not illustrated) extends to the terminal region side (not illustrated).

In this embodiment, description is made of a case where the first extending wiring line 2A and the second extending wiring line 2B are extending wiring lines of gate electrodes. However, the disclosure is not limited thereto. A type of the extending wiring lines 2A and 2B is not particularly limited as long as the wiring lines are dedicated for signals supplied from the terminal portion (not illustrated) included in the terminal region TA (see FIG. 2A and FIG. 2B).

In the display region AA on the outer side of the slit (BH), that is, on the left side in the drawing sheet on the outer side of the slit (BH), the first extending wiring line 2A is provided. In the terminal region TA on the outer side of the slit (BH), that is, on the right side in the drawing sheet on the outer side of the slit (BH), the second extending wiring line 2B is provided.

Note that, the slit (BH) from which at least a part of one or more inorganic films provided on the film substrate 10 being a flexible substrate is removed, is similar to that in the comparative example described above, and is an opening formed from, for example, an one end to the other end of the flexible organic EL display device 50.

Further, the contact hole CH1 and the contact hole CH2 are formed in the first insulating layer 18 and the second insulating layer 20 so that the first extending wiring line 2A and the second extending wiring line 2B are exposed.

In the manufacturing processes of the flexible organic EL display device 50, after the process illustrated in FIG, 1C, as illustrated in FIG. 1D, a first conductive member 9A electrically connected to the first extending wiring line 2A through the contact hole CH1 and a second conductive member 9C electrically connected to the second extending wiring line 2B through the contact hole CH2 are formed on the second insulating layer 20, and a third conductive member 9B is formed in the slit (BH).

After that, the photosensitive PI layer (polyimide resin layer containing a photosensitive material) is formed as a first resin layer 13 on the entire glass substrate 1. In the patterning process of the first resin layer 13, exposure and development are performed. As illustrated in FIG. 1E, the slit (BH) is filled, and the first resin layer 13 remains to cover the first conductive member 9A, the second conductive member 9C, and the third conductive member 9B.

As described above, in this embodiment, the first resin layer 13 is formed to fill the slit (BH) and cover the first conductive member 9A and the second conductive member 9C. Thus, as compared to the example described above, the material for forming the first resin layer 13 can be used efficiently.

In the patterning process of the first resin layer 13, an opening TH1 overlapping with the first conductive member 9A, an opening TH4 overlapping with the second conductive member 9C, and an opening TH2 and an opening TH3 overlapping with the third conductive member 9B are formed in the first resin layer 13 in a plan view.

In this embodiment, description is made of a case where the first resin layer 13 is formed of a polyimide resin containing a positive-working type photosensitive material. However, the disclosure is not limited thereto. The first resin layer 13 may be formed of a polyimide resin containing a negative-working type photosensitive material, and may be formed of a polyimide resin without a photosensitive material. Further, other than a polyimide resin, for example, an acrylic resin, an epoxy resin, and an polyamide resin may be used.

Note that, in a case where the first resin layer 13 is formed of a resin without a photosensitive material, dry etching or a wet etching is performed with a resist film having a predetermined shape as a mask. In this manner, the formation of the openings TH1 to TH4 and the patterning of the first resin layer 13 can be performed.

Further, as illustrated in FIG. 1F, a fourth conductive member 22A electrically connected to the first conductive member 9A and the third conductive member 9B through the opening TH1 and the opening TH2 and a fifth conductive member 22b electrically connected to the second conductive member 9C and the third conductive member 9B through the opening TH3 and the opening TH4 are formed on the first resin layer 13.

As described above, on the first resin layer 13, the fourth conductive member 22A and the fifth conductive member 22B are formed. Accordingly, the first extending wiring line 2A and the second extending wiring line 2B are connected electrically.

Note that, the first resin layer 13 may be formed of the same material as the organic interlayer layer 21 being a flattening film in the TFT layer 4 including a thin film transistor element (TFT element) as an active element.

Further, as illustrated in FIG. 1G, a second resin layer 14 is formed to cover the first resin layer 13, the fourth conductive member 22A, and the fifth conductive member 22B.

In this embodiment, description is made of a case where the second resin layer 14 is formed of a polyimide resin containing a positive-working type photosensitive material. However, the disclosure is not limited thereto. The second resin layer 14 may be formed of a polyimide resin containing a negative-working type photosensitive material, and may be formed of a polyimide resin without a photosensitive material. Further, other than a polyimide resin, for example, an acrylic resin, an epoxy resin, and an polyamide resin may be used.

The first resin layer 13 included in the flexible organic EL display device 50 according to this embodiment functions as the first photosensitive PI layer 61A having the predetermined shape (function of filling the slit (BH)) and the second photosensitive PI layer 62 (function as a flattening film), which are included in the flexible organic EL display device 70 being the comparative example illustrated in FIG. 5G.

Further, the loss of the material, which is caused in the patterning process of the first resin layer 13 included in the flexible organic EL display device 50 according to this embodiment, is less than those in the patterning processes of the first photosensitive PI layer 61 and the second photosensitive PI layer 62 included in the flexible organic EL display device 70.

This difference in loss of the material is caused because, in the patterning process of the first photosensitive PI layer 61 included in the flexible organic EL display device 70, almost all of the applied first photosensitive PI layer 61 is removed except for the remaining first photosensitive PI layer 61A having the predetermined shape.

Further, in the flexible organic EL display device 50 according to this embodiment, as illustrated in FIG. 1D and FIG. 1E, before the first resin layer 13 is formed, the contact hole CH1 and the contact hole CH2 are filled with the first conductive member 9A and the second conductive member 9C.

Therefore, a residue of the first resin layer 13 does not remain in the contact hole CH1 and the contact hole CH2, and hence connection failure between the wiring lines can be suppressed.

FIG. 2A is a view for illustrating a schematic configuration of the vicinity of the slit (BH) including the bending region (BA) of the flexible organic EL display device 50. FIG. 2B is a view for illustrating a schematic configuration of the display region (AA) of the flexible organic EL display device 50.

The laser light is emitted from a side of the glass substrate 1 being a non-flexible substrate illustrated in FIG. 1G, and ablation is caused at a boundary surface between the polyimide resin layer 12 and the glass substrate 1.

Then, the glass substrate 1 is peeled off from the polyimide resin layer 12, and the film substrate 10 being a flexible substrate is attached to the polyimide resin layer 12 through intermediation of the adhesive layer 11 provided on one surface of the film substrate 10. In this manner, the flexible organic EL display device 50 illustrated in FIG. 2A and FIG. 2B is completed.

The bending region (BA) of the flexible organic EL display device 50 illustrated in FIG. 2A is a region overlapping with the slit (BH) illustrated in FIG, 1C in a plan view, and a region between the fourth conductive member 22A and the fifth conductive member 22B.

That is, the flexible organic EL display device 50 can be bent in a portion without the inorganic films the slit (BH).

Note that, the configuration of the display region (AA) of the flexible organic EL display device 50 illustrated in FIG. 2B is similar to the configuration of the display region (AA) of the flexible organic EL display device 70, which is already described with FIG. 6B, and description thereof is omitted.

It is preferred that the first extending wiring line 2A and the second extending wiring line 2B included in the flexible organic EL display device 50 illustrated in FIG. 2A be formed of the same material. For example, it is preferred that the first extending wiring line 2A and the second extending wiring line 2B be formed of a layer forming the gate electrode 2G of the transistor element (TFT element) included in the display region (AA) of the flexible organic EL display device 50 illustrated in FIG. 2B.

As described above, the first extending wiring line 2A and the second extending wiring line 2B are formed by the layer forming the gate electrode 2G. With this, the first extending wiring line 2A and the second extending wiring line 2B can be formed in the process of forming the gate electrode 2G.

Further, the third conductive member 9B included in the flexible organic EL display device 50 illustrated in FIG. 2A is formed on the bending region (BA). Thus, it is preferred that the third conductive member 9B be formed of a metal material, specifically, a metal material containing at least one of aluminum, titanium, and copper.

Moreover, it is preferred that the first conductive member 9A, the second conductive member 9C, and the third conductive member 9B included in the flexible organic EL display device 50 illustrated in FIG. 2A be formed of the same material. For example, it is preferred that the first conductive member 9A, the second conductive member 9C, and the third conductive member 9B be formed of a layer forming the source electrode 9S and the drain electrode 9D of the transistor element (TFT element) included in the display region (AA) of the flexible organic EL display device 50 illustrated in FIG. 2B.

In this embodiment, the first conductive member 9A, the second conductive member 9C, the third conductive member 9B, the source electrode 9S, and the drain electrode 9D are formed of layered films obtained by layering titanium (Ti), aluminum (Al), and titanium (Ti) in the stated order. However, the disclosure is not limited thereto. In the case where the semiconductor film 15 is, for example, an oxide semiconductor film containing indium (In), gallium (Ga), and zinc (Zn) or an oxide semiconductor film containing indium (In), gallium (Ga), and zinc (Zn), which is manufactured in a manufacturing process of low-temperature polysilicon (LTPS), a layered film containing copper (Cu) and titanium (Ti) may be used for the material for forming the source electrode 9S and the drain electrode 9D.

As described above, the first conductive member 9A, the second conductive member 9C, and the third conductive member 9B are formed of the layer forming the source electrode 9S and the drain electrode 9D. Accordingly, the first conductive member 9A, the second conductive member 9C, and the third conductive member 9B can be formed in the process of forming the source electrode 9S and the drain electrode 9D.

Further, it is preferred that the fourth conductive member 22A and the fifth conductive member 22B included in the flexible organic EL display device 50 illustrated in FIG. 2A be formed of the same material. For example, it is preferred that the fourth conductive member 22A and the fifth conductive member 22B be formed of a layer forming the first electrode (anode) 22 or the second electrode (for example, cathode) 25 of the organic EL display element 5 included in the display region (AA) of the flexible organic EL display device 50 illustrated in FIG. 2B.

In this embodiment, the fourth conductive member 22A, the fifth conductive member 22B, and the first electrode (anode) 22 are formed of layered films obtained by layering indium tin oxide, an alloy containing silver (Ag), and indium tin oxide in the stated order. However, the disclosure is not limited thereto.

As described above, the fourth conductive member 22A and the fifth conductive member 22B are formed of the layer forming the first electrode (anode) 22 included in the organic EL display element 5. Accordingly, the fourth conductive member 22A and the fifth conductive member 22B can be formed in the process of forming the first electrode (anode) 22.

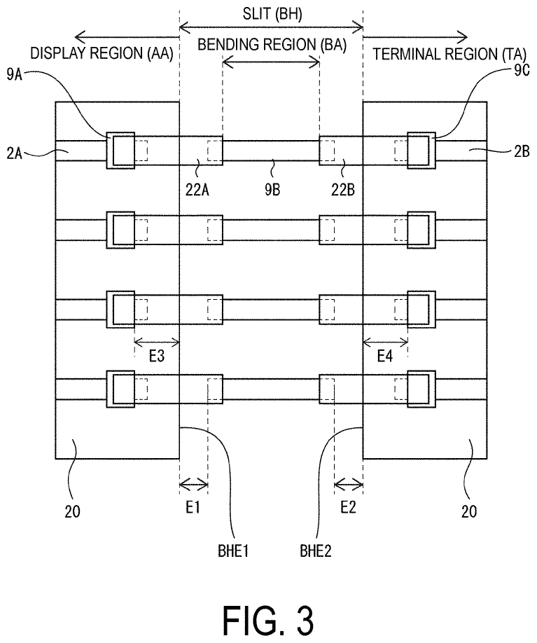

FIG. 3 is a plan view of the vicinity of the slit (BH) including the bending region (BA) of the flexible organic EL display device 50 illustrated in FIG. 2A.

The inventors of the disclosure have found out that the layer forming the first conductive member 9A, the second conductive member 9C, and the third conductive member 9B, which is supposed to be removed, is liable to remain because the inorganic film is large in thickness at an end BHE1 on the display region (AA) side and an end BHE2 on the terminal region (TA) side of the slit (BH).

A residue of the layer forming the first conductive member 9A, the second conductive member 9C, and the third conductive member 9B, which remains at the end BHE1 on the display region (AA) side and the end BHE2 on the terminal region (TA) side of the slit (BH) disadvantageously causes leak from a plurality of third conductive members 9B formed in the slit (BH).

In view of this, it is preferred that the third conductive member 9B be prevented from overlapping with the end BHE1 on the display region (AA) side and the end BHE2 on the terminal region (TA) side of the slit (BH) in a plan view.

Specifically, for example, the third conductive member 9B is formed in the slit (BH) to be away from the end BHE1 on the display region (AA) side of the slit (BH) by a distance El (for example, 1 μm) and from the end BHE2 on the terminal region (TA) side of the slit (BH) by a distance E2 (for example, 1 μm).

Note that, the distance E1 (for example, 1 μm) and the distance E2 (for example, 1 μm) described above are merely examples, and it is needless to mention that the distance E1 and the distance E2 are changed as appropriate depending on a depth and a shape of the slit (BH).

A residue of the layer forming the first conductive member 9A, the second conductive member 9C, and the third conductive member 9B, which remains at the end BHE1 on the display region (AA) side and the end BHE2 on the terminal region (TA) side of the slit (BH) disadvantageously causes leak from the plurality of third conductive members 9B formed in the slit (BH). However, with the above-mentioned configuration, such leak can be suppressed.

Further, it is preferred that the first conductive member 9A and the second conductive member 9C be prevented from overlapping with the end BHE1 on the display region (AA) side and the end BHE2 on the terminal region (TA) side of the slit (BH) in a plan view.

Specifically, for example, the first conductive member 9A and the second conductive member 9C are formed to be away from the end BHE1 on the display region (AA) side of the slit (BH) by a distance E3 (for example, 1 μm) and from the end BHE2 on the terminal region (TA) side of the slit (BH) by a distance E4 (for example, 1 μm).

Note that, the distance E3 (for example, 1 μm) and the distance E4 (for example, 1 μm) described above are merely examples, and it is needless to mention that the distance E3 and the distance E4 are changed as appropriate depending on a depth and a shape of the slit (BH).

A residue of the layer forming the first conductive member 9A, the second conductive member 9C, and the third conductive member 9B, which remains at the end BHE1 on the display region (AA) side and the end BHE2 on the terminal region (TA) side of the slit (BH) disadvantageously causes leak from a plurality of first conductive members 9A and a plurality of second conductive members 9C. However, with the above-mentioned configuration, such leak can be suppressed.

### Second Embodiment

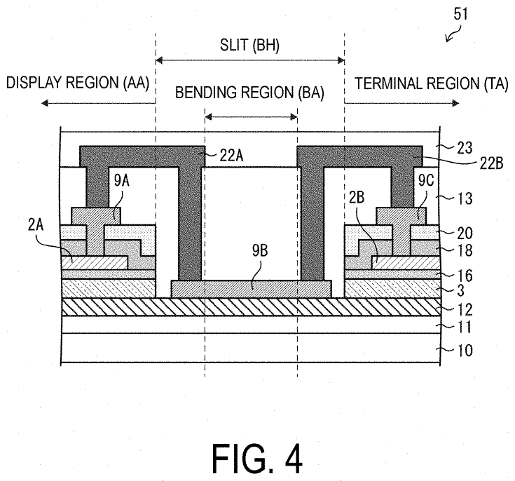

Next, with reference to FIG. 4, description is made of the second embodiment of the disclosure. This embodiment is different from the first embodiment in that the second resin layer covering the first resin layer 13, the fourth conductive member 22A, and the fifth conductive member 22B is made of the same material as the organic insulating film (also referred to as an edge cover layer) 23 included in the display region (AA) of a flexible organic EL display device 51. The other matter are the same as those described in the first embodiment. For convenience of descriptions, members having the same functions as those of the members illustrated in the diagrams in the first embodiment are denoted by the same reference numerals, and descriptions thereof will be omitted.

FIG. 4 is a view for illustrating a schematic configuration of the vicinity of the slit (BH) including the bending region (BA) of the flexible organic EL display device 51.

Note that, although not illustrated, the schematic configuration of the display region (AA) of the flexible organic EL display device 51 is the same as the schematic configuration of the display region (AA) of the flexible organic EL display device 50 illustrated in FIG. 2B.

In the flexible organic EL display device 51, the second resin layer covering the first resin layer 13, the fourth conductive member 22A, and the fifth conductive member 22B is formed of the same material as the organic insulating film (also referred to as an edge cover layer) 23 included in the display region (AA) of the flexible organic EL display device 51.

As described above, the second resin layer covering the first resin layer 13, the fourth conductive member 22A, and the fifth conductive member 22B is formed of the same material as the organic insulating film 23 included in the display region (AA) of the flexible organic EL display device 51. With this, the second resin layer can be formed in the process of forming the organic insulating film 23.

### Supplement

In order to achieve the above-mentioned object, according to a first aspect of the disclosure, there is provided a flexible display device including a flexible substrate, and an active element and a display element, which are provided on the flexible substrate. The active element and the display element are provided in a display region. In a periphery of the display region, a frame region is provided, which includes a slit obtained by removing at least part of one or more inorganic films provided on the flexible substrate, and a terminal region including a terminal portion. A first extending wiring line is provided on the display region side on an outer side of the slit, and a second extending wiring line is provided on the terminal region side on an outer side of the slit. In the one or more inorganic films, a first opening is formed to expose the first extending wiring line, and a second opening is formed to expose the second extending wiring line. On the one or more inorganic films, a first conductive member electrically connected to the first extending wiring line through the first opening and a second conductive member electrically connected to the second extending wiring line through the second opening are formed. A third conductive member is formed in the slit. In a plan view, a third opening overlapping with the first conductive member, a fourth opening overlapping with the second conductive member, and a fifth opening and a sixth opening overlapping with the third conductive member are formed in a first resin layer configured to fill the slit and cover the first conductive member, the second conductive member, and the third conductive member. On the first resin layer, a fourth conductive member configured to electrically connect the first conductive member and the third conductive member through the third opening and the fifth opening and a fifth conductive member configured to electrically connect the second conductive member and the third conductive member through the fourth opening and the sixth opening are formed. A bending region overlaps with the slit in a plan view.

With the flexible display device according to a second aspect of the disclosure, in the first aspect, it is preferred that the third conductive member be prevented from overlapping with an end on the display region side and an end on the terminal region side of the slit in a plan view.

With the flexible display device according to a third aspect of the disclosure, in the first aspect or the second aspect, it is preferred that the first conductive member and the second conductive member be prevented from overlapping with the end on the display region side and the end on the terminal region side of the slit in a plan view.

With the flexible display device according to a fourth aspect of the disclosure, in any of the first aspect to the third aspect, the third conductive member may be a metal material containing at least one of aluminum, titanium, and copper.

With the flexible display device according to a fifth aspect of the disclosure, in any of the first aspect to the fourth aspect, the first extending wiring line and the second extending wiring line may be formed of the same material. The first conductive member, the second conductive member, and the third conductive member may be formed of the same material. The fourth conductive member and the fifth conductive member may be formed of the same material.

With the flexible display device according to a sixth aspect of the disclosure, in any of the first aspect to the fifth aspect, the active element may include one layer of the one or more inorganic films, a first electrode layer below the one layer, and a second electrode layer above the one layer. The first extending wiring line and the second extending wiring line may be formed of the same material as the first electrode layer. The first conductive member, the second conductive member, and the third conductive member may be formed of the same material as the second electrode layer.

With the flexible display device according to a seventh aspect of the disclosure, in any of the first aspect to the sixth aspect, the display element may include a third electrode layer being a bottom layer, which is formed above the active element, and the fourth conductive member and the fifth conductive member may be formed of the same material as the third electrode layer.

With the flexible display device according to an eighth aspect of the disclosure, in the sixth aspect, the active element may be a transistor element. The first electrode layer may be a layer forming a gate electrode. The second electrode layer may be a layer forming a source electrode and a drain electrode.

With the flexible display device according to a ninth aspect of the disclosure, in the seventh aspect, the display element may be an organic EL display element, and the third electrode layer may be a layer forming an anode or a cathode.

With the flexible display device according to a tenth aspect of the disclosure, in the sixth aspect or the eighth aspect, the second electrode layer may be a layered film obtained by layering titanium, aluminum, and titanium in the stated order, or a layered film of titanium and copper.

With the flexible display device according to an eleventh aspect of the disclosure, in the seventh aspect or the ninth aspect, the third electrode layer may be a layered film obtained by layering indium tin oxide, an alloy containing silver, and indium tin oxide in the stated order.

With the flexible display device according to a twelfth aspect of the disclosure, in any of the first aspect to the eleventh aspect, it is preferred that the first resin layer be formed of the same material as a flattening film in a TFT layer including the active element.

With the flexible display device according to a thirteenth aspect of the disclosure, in any of the first aspect to the twelfth aspect, it is preferred that a second resin layer be formed to cover the fourth conductive member, the fifth conductive member, and the first resin layer.

With the flexible display device according to a fourteenth aspect of the disclosure, in the thirteenth aspect, it is preferred that the second resin layer be formed of the same material as an edge cover layer configured to cover an end of the third electrode layer provided as a bottom layer with the display element included in the display region.

In order to achieve the above-mentioned object, according to the fifteenth aspect of the disclosure, there is provided a method of manufacturing a flexible display device. The flexible display device includes a display region, which includes an active element and a display element, and a frame region, which includes a bending region formed in a periphery of the display region and a terminal region including a terminal portion. The method includes a first step of forming, on a non-flexible substrate, a plurality of inorganic films including a first extending wiring line and a second extending wiring line, which are away from each other, a second step of forming a slit by removing at least part of the plurality of inorganic films in a part of the frame region, and forming, in the plurality of inorganic films, a first opening to expose the first extending wiring line and a second opening to expose the second extending wiring line, a third step of forming a first conductive member electrically connected to the first extending wiring line through the first opening and a second conductive member electrically connected to the second extending wiring line through the second opening on the plurality of inorganic films, and forming a third conductive member in the slit, a fourth step of forming a first resin layer configured to fill the slit and cover the first conductive member, the second conductive member, and the third conductive member, and forming, in the first resin layer, a third opening overlapping with the first conductive member, a fourth opening overlapping with the second conductive member, and a fifth opening and a sixth opening overlapping with the third conductive member in a plan view, a fifth step of forming, on the first resin layer, a fourth conductive member electrically connecting the first conductive member and the third conductive member through the third opening and the fifth opening, and a fifth conductive member electrically connecting the second conductive member and the third conductive member through the fourth opening and the sixth opening so that a region between the fourth conductive member and the fifth conductive member is prevented from overlapping with the slit in a plan view, a sixth step of forming a second resin layer to cover the fourth conductive member, the fifth conductive member, and the first resin layer, a seventh step peeling off the non-flexible substrate, and an eighth step of attaching a flexible substrate to a surface from which the non-flexible substrate is peeled off.

With the method of manufacturing a flexible display device according to a sixteenth aspect of the disclosure, in the fifteenth aspect, in the third step, it is preferred that the third conductive member be formed to be prevented from overlapping with an end on the display region side and an end on the terminal region side of the slit in a plan view.

With the method of manufacturing a flexible display device according to a seventeenth aspect of the disclosure, in the fifteenth aspect or the sixteenth aspect, in the third step, it is preferred that the first conductive member and the second conductive member be formed to be prevented from overlapping with the end on the display region side and the end on the terminal region side of the slit in a plan view.

With the method of manufacturing a flexible display device according to a eighteenth aspect of the disclosure, in any one of the fifteenth aspect to the seventeenth aspect, the active element may include one layer of the plurality of inorganic films other than a layer forming the first extending wiring line and the second extending wiring line, a first electrode layer below the one layer, and a second electrode layer above the one layer. In the first step, the first extending wiring line and the second extending wiring line may be formed in the same step of forming the first electrode layer. In the third step, the first conductive member, the second conductive member, and the third conductive member may be formed in the same step of forming the second electrode layer.

With the method of manufacturing a flexible display device according to a nineteenth aspect of the disclosure, in any one of the fifteenth aspect to the eighteenth aspect, the display element may be formed above the active element, and includes a third electrode layer as a bottom layer, and, in the fifth step, the fourth conductive member and the fifth conductive member may be formed in the same step of forming the third electrode layer.

With the method of manufacturing a flexible display device according to a twelfth aspect of the disclosure, in the eighteenth aspect, the active element may be a transistor element. The first electrode layer may be a layer forming a gate electrode. The second electrode layer may be a layer forming a source electrode and a drain electrode.

With the method of manufacturing a flexible display device according to a twenty-first aspect of the disclosure, in the nineteenth aspect, the display element may be an organic EL display element, and the third electrode layer may be a layer forming an anode or a cathode.

With the method of manufacturing a flexible display device according to a twenty-second aspect of the disclosure, in any one of the fifteenth aspect to the twenty-first aspect, the second resin layer formed in the sixth step may be formed in the same step of forming an edge cover layer configured to cover an end of the third electrode layer provided as a bottom layer with the display element included in the display region.

### Additional Items

The disclosure is not limited to each of the embodiments stated above, and various modifications may be implemented within a range not departing from the scope of the claims. Embodiments obtained by appropriately combining technical approaches stated in each of the different embodiments also fall within the scope of the technology of the disclosure. Moreover, novel technical features may be formed by combining the technical approaches stated in each of the embodiments.

### INDUSTRIAL APPLICABILITY

The disclosure is applicable to a flexible display device and a method of manufacturing the flexible display device.

### REFERENCE SIGNS LIST

1 Glass substrate (non-flexible substrate)

2A First extending wiring line

2B Second extending wiring line

2G Gate electrode

3 Moisture-proof layer

4 TFT layer

5 Organic EL display element (display element)

9A First conductive member

9B Third conductive member

9C Second conductive member

9S Source electrode

9D Drain electrode

10 Film substrate (flexible substrate)

12 Polyimide resin layer

13 First resin layer

14 Second resin layer

16 Gate insulating layer

18 First insulating layer

20 Second insulating layer

22 First electrode

22A Fourth conductive member

22B Fifth conductive member

23 Organic insulating film (edge cover layer)

50 Flexible organic EL display device (flexible display device)

51 Flexible organic EL display device (flexible display device)

AA Display region

TA Terminal region

EA Frame region

BA Bending region

BH Slit

CH1 Contact hole (first opening)

CH2 Contact hole (second opening)

TH1 Opening (third opening)

TH2 Opening (fifth opening)

TH3 Opening (sixth opening)

TH4 Opening (fourth opening)

1: A flexible display device, comprising:
a flexible substrate; and
an active element and a display element, which are provided on the flexible substrate,
wherein the active element and the display element are provided in a display region,
in a periphery of the display region, a frame region is provided, the frame region including
a slit obtained by removing at least part of one or more inorganic films provided on the flexible substrate, and
a terminal region including a terminal portion,
a first extending wiring line is provided on the display region side on an outer side of the slit, and a second extending wiring line is provided on the terminal region side on an outer side of the slit,
in the one or more inorganic films, a first opening is formed to expose the first extending wiring line, and a second opening is formed to expose the second extending wiring line,
on the one or more inorganic films, a first conductive member electrically connected to the first extending wiring line through the first opening and a second conductive member electrically connected to the second extending wiring line through the second opening are formed,
a third conductive member is formed in the slit,
in a plan view, a third opening overlapping with the first conductive member, a fourth opening overlapping with the second conductive member, and a fifth opening and a sixth opening overlapping with the third conductive member are formed in a first resin layer configured to fill the slit and cover the first conductive member, the second conductive member, and the third conductive member,
on the first resin layer, a fourth conductive member configured to electrically connect the first conductive member and the third conductive member through the third opening and the fifth opening and a fifth conductive member configured to electrically connect the second conductive member and the third conductive member through the fourth opening and the sixth opening are formed, and
a bending region overlaps with the slit in a plan view.

2: The flexible display device according to claim 1,
wherein the third conductive member is prevented from overlapping with an end on the display region side and an end on the terminal region side of the slit in a plan view.

3: The flexible display device according to claim 1,
wherein the first conductive member and the second conductive member are prevented from overlapping with the end on the display region side and the end on the terminal region side of the slit in a plan view.

4: The flexible display device according to claim 1,
wherein the third conductive member comprises a metal material containing at least one of aluminum, titanium, and copper.

5: The flexible display device according to claim 1,
wherein the first extending wiring line and the second extending wiring line are formed of the same material,
the first conductive member, the second conductive member, and the third conductive member are formed of the same material, and
the fourth conductive member and the fifth conductive member are formed of the same material.

6: The flexible display device according to claim 1,
wherein the active element includes one layer of the one or more inorganic films, a first electrode layer below the one layer, and a second electrode layer above the one layer,
the first extending wiring line and the second extending wiring line are formed of the same material as the first electrode layer, and
the first conductive member, the second conductive member, and the third conductive member are formed of the same material as the second electrode layer.

7: The flexible display device according to claim 1,
wherein the display element includes a third electrode layer being a bottom layer, which is formed above the active element, and
the fourth conductive member and the fifth conductive member are formed of the same material as the third electrode layer.

8: The flexible display device according to claim 6,
wherein the active element comprises a transistor element,
the first electrode layer comprises a layer forming a gate electrode, and
the second electrode layer comprises a layer forming a source electrode and a drain electrode.

9: The flexible display device according to claim 7,
wherein the display element comprises an organic EL display element, and
the third electrode layer comprises a layer forming an anode or a cathode.

10: The flexible display device according to claim 6,
wherein the second electrode layer comprises a layered film obtained by layering titanium, aluminum, and titanium in the stated order, or a layered film of titanium and copper.

11: The flexible display device according to claim 7,
wherein the third electrode layer comprises a layered film obtained by layering indium tin oxide, an alloy containing silver, and indium tin oxide in the stated order.

12: The flexible display device according to claim 1,
wherein the first resin layer is formed of the same material as a flattening film in a TFT layer including the active element.

13: The flexible display device according to claim 1,
wherein a second resin layer is formed to cover the fourth conductive member, the fifth conductive member, and the first resin layer.

14: The flexible display device according to claim 13,
wherein the second resin layer is formed of the same material as an edge cover layer configured to cover an end of the third electrode layer provided as a bottom layer with the display element included in the display region.

15: A method of manufacturing a flexible display device, the flexible display device including a display region, which includes an active element and a display element, and a frame region, which includes a bending region formed in a periphery of the display region and a terminal region including a terminal portion, the method comprising:
a first step of forming, on a non-flexible substrate, a plurality of inorganic films including a first extending wiring line and a second extending wiring line, which are away from each other;
a second step of forming a slit by removing at least part of the plurality of inorganic films in a part of the frame region, and forming, in the plurality of inorganic films, a first opening to expose the first extending wiring line and a second opening to expose the second extending wiring line;
a third step of forming a first conductive member electrically connected to the first extending wiring line through the first opening and a second conductive member electrically connected to the second extending wiring line through the second opening on the plurality of inorganic films, and forming a third conductive member in the slit;
a fourth step of forming a first resin layer configured to fill the slit and cover the first conductive member, the second conductive member, and the third conductive member, and forming, in the first resin layer, a third opening overlapping with the first conductive member, a fourth opening overlapping with the second conductive member, and a fifth opening and a sixth opening overlapping with the third conductive member in a plan view;
a fifth step of forming, on the first resin layer, a fourth conductive member electrically connecting the first conductive member and the third conductive member through the third opening and the fifth opening and a fifth conductive member electrically connecting the second conductive member and the third conductive member through the fourth opening and the sixth opening so that a region between the fourth conductive member and the fifth conductive member is prevented from overlapping with the slit in a plan view;
a sixth step of forming a second resin layer to cover the fourth conductive member, the fifth conductive member, and the first resin layer;
a seventh step of peeling off the non-flexible substrate; and
an eighth step of attaching a flexible substrate to a surface from which the non-flexible substrate is peeled off.

16: The method of manufacturing a flexible display device according to claim 15,
wherein, in the third step, the third conductive member is formed to be prevented from overlapping with an end on the display region side and an end on the terminal region side of the slit in a plan view.

17: The method of manufacturing a flexible display device according to claim 15,
wherein, in the third step, the first conductive member and the second conductive member are formed to be prevented from overlapping with the end on the display region side and the end on the terminal region side of the slit in a plan view.

18: The method of manufacturing a flexible display device according to claim 15,
wherein the active element includes one layer of the plurality of inorganic films other than a layer forming the first extending wiring line and the second extending wiring line, a first electrode layer below the one layer, and a second electrode layer above the one layer,
in the first step, the first extending wiring line and the second extending wiring line are formed in the same step of forming the first electrode layer, and
in the third step, the first conductive member, the second conductive member, and the third conductive member are formed in the same step of forming the second electrode layer.

19: The method of manufacturing a flexible display device according to claim 15,
wherein the display element is formed above the active element, and includes a third electrode layer as a bottom layer, and
in the fifth step, the fourth conductive member and the fifth conductive member are formed in the same step of forming the third electrode layer.

20: The method of manufacturing a flexible display device according to claim 18,
wherein the active element comprises a transistor element,
the first electrode layer comprises a layer forming a gate electrode, and
the second electrode layer comprises a layer forming a source electrode and a drain electrode.

21-22. (canceled)
